(19) United States
(12) Patent Application Publication
(10) Pub. No.: US 2023/0164955 A1
(43) Pub. Date: May 25, 2023

(54) HEAT DISSIPATION MEMBER

(71) Applicant: PEGATRON CORPORATION, Taipei City (TW)

(72) Inventors: YU-YING CHUANG, TAIPEI CITY (TW); WEI-PANG LEE, TAIPEI CITY (TW)

(21) Appl. No.: 17/953,427

(22) Filed: Sep. 27, 2022

(30) Foreign Application Priority Data
Nov. 24, 2021 (TW) 110143669

(51) Int. Cl. H05K 7/20; F28F 3/06

(52) U.S. Cl. CPC H05K 7/20418; F28F 3/06; F28F 2240/00; F28F 2250/10

(57) ABSTRACT

The disclosure discloses a heat dissipation member, including a base plate, a plurality of first sheet structures, and a plurality of second sheet structures. Each first sheet structure is vertically arranged on a side of the base plate, and an end of the each first sheet structure is arranged adjacent to a side edge of the base plate. A spacing between two adjacent first sheet structures gradually increases from a first side edge of the base plate to a second side edge of the base plate. The first side edge is not adjacent to the second side edge. Each second sheet structure is arranged between two adjacent first sheet structures.

### TECHNICAL FIELD

The disclosure relates to a heat dissipation member, and in particular, to a wall-mounted heat dissipation member.

### BACKGROUND

Referring to FIG. 1 and FIG. 2 together, FIG. 1 and FIG. 2 are respectively a three-dimensional schematic view and a top view of a conventional heat dissipation member. The conventional heat dissipation member A includes a base plate A1 and a plurality of fins A2. Each fin A2 is vertically arranged on a wide side surface A11 of the base plate A1. The each fin A2 is substantially a rectangular sheet structure, and the fins A2 are arranged on the base plate A1 in parallel with each other. An airflow channel A3 is formed between the fins A2 adjacent to each other.

When the heat dissipation member A is fixed to a to-be-dissipated member in a form of wall hanging (that is, the wide side surface A11 of the base plate A1 is substantially perpendicular to the ground), a wide side surface A21 of the each fin A2 and the wide side surface A11 of the base plate A1 jointly limit a direction of air flow, and air can only move along a path P that is substantially perpendicular to the ground. Therefore, heat energy is easily accumulated in a region B shown in the figure, causing a poor overall heat dissipation effect of the heat dissipation member A.

### SUMMARY

The disclosure discloses a heat dissipation member. The heat dissipation member is mainly configured to alleviate a problem that in the conventional heat dissipation member, heat energy is easily accumulated in a local region of the heat dissipation member, causing a poor overall heat dissipation effect of the heat dissipation member.

An embodiment of the disclosure discloses a heat dissipation member, including a base plate, a plurality of first sheet structures, and a plurality of second sheet structures. The base plate includes a first side edge and a second side edge that are not adjacent. Each first sheet structure is vertically arranged on the base plate. One end of the each first sheet structure is arranged adjacent to the first side edge. A spacing between two adjacent first sheet structures gradually increases from the first side edge to the second side edge, and an other end of a part of the first sheet structures is arranged adjacent to a third side edge of the base plate. The third side edge is adjacent to the first side edge. One end of each second sheet structure is arranged between the two adjacent first sheet structures.

Based on the above, through design of the plurality of first sheet structures and the plurality of second sheet structures, the heat dissipation member of the disclosure can effectively alleviate the problem that the conventional heat dissipation member is prone to heat energy accumulation, and can effectively improve the overall heat dissipation effect of the heat dissipation member.

For further understanding of features and technical content of the disclosure, refer to the following detailed description and accompanying drawings related to the disclosure. However, the description and accompanying drawings are only used to illustrate the disclosure, and are not intended to limit the protection scope of the disclosure.

### BRIEF DESCRIPTION OF THE DRAWINGS

FIG. 1 and FIG. 2 are a schematic three-dimensional view and a top view of a conventional heat sink respectively.

FIG. 3 is a schematic three-dimensional view of a first embodiment of a heat dissipation member according to the disclosure.

FIG. 4 is a top view of a first embodiment of a heat dissipation member according to the disclosure.

FIG. 5 is a schematic diagram of air flow of a first embodiment of the heat dissipation member according to the disclosure.

FIG. 6 is a schematic diagram of orthographic projections of each first sheet structure and each second sheet structure on a side surface of a base plate of a first embodiment of a heat dissipation member according to the disclosure.

FIG. 7 is a top view of a second embodiment of a heat dissipation member according to the disclosure.

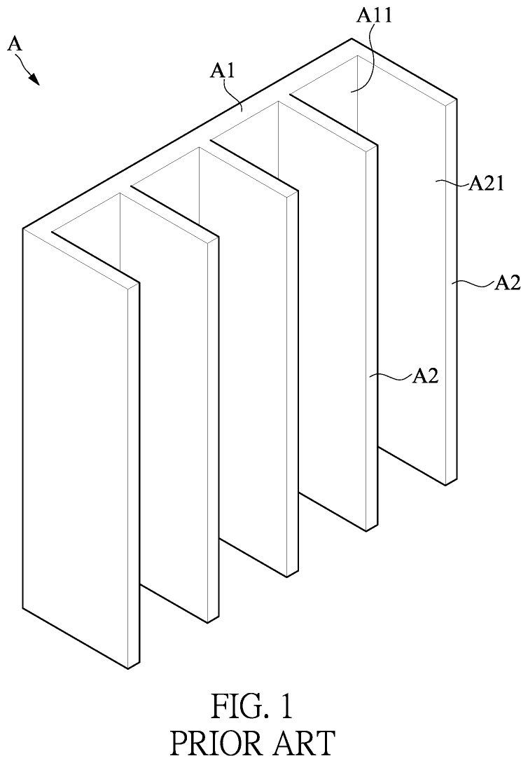

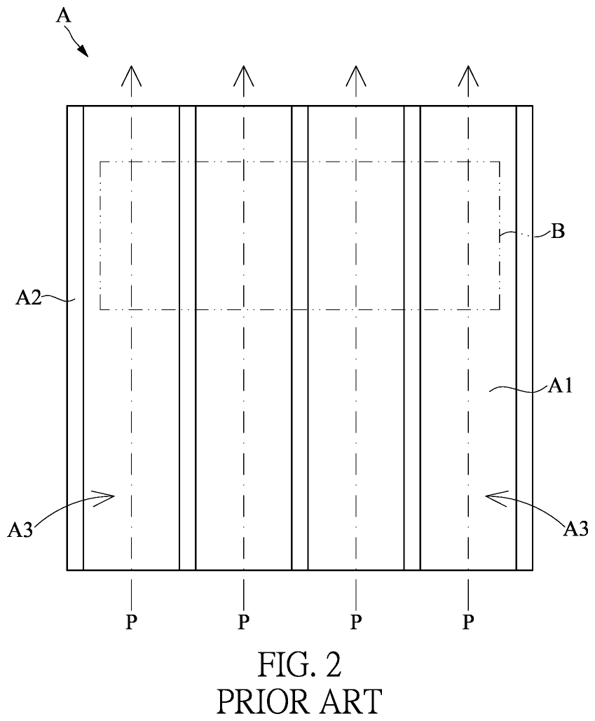

### DETAILED DESCRIPTION

In the following description, if “refer to a specific drawing” or “as shown in a specific drawing” is indicated, it is only used to emphasize that in a subsequent description, most of the related content mentioned is shown in the specific drawing, but does not limit that reference can only be made to the specific drawing in the subsequent description.

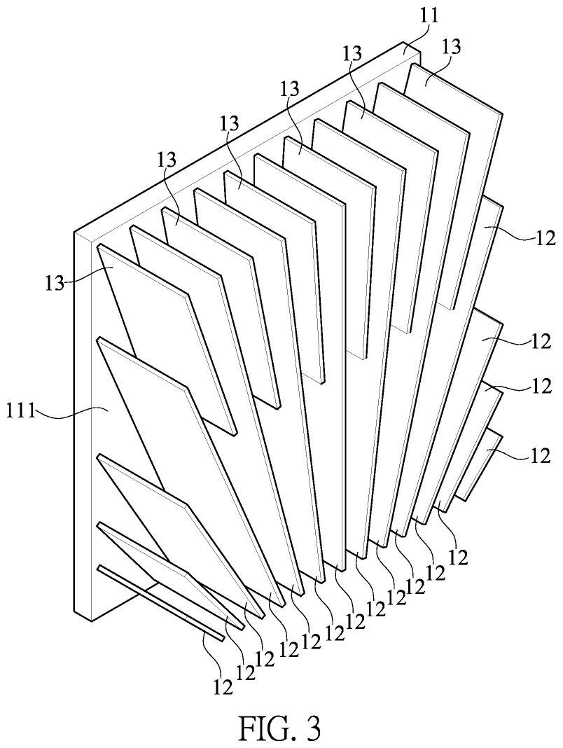

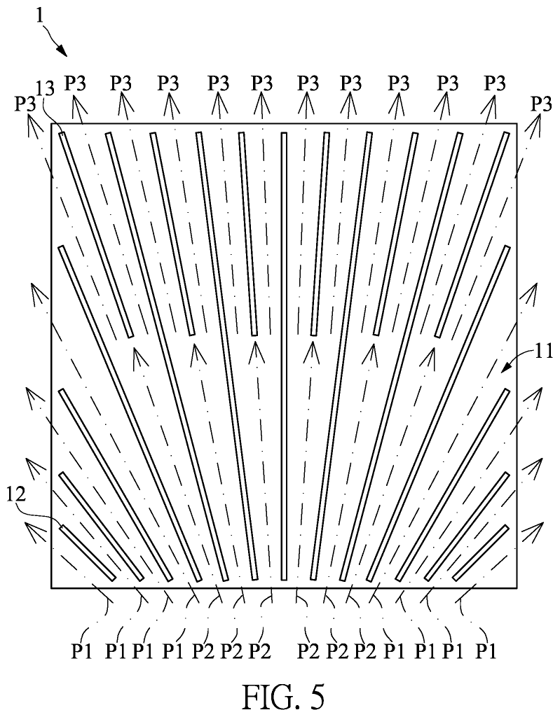

Referring to FIG. 3 to FIG. 5 together, FIG. 3 to FIG. 5 are respectively a schematic three-dimensional view, a top view, and a schematic diagram of air flow of a first embodiment of a heat dissipation member according to the disclosure. The heat dissipation member 1 of the disclosure includes a base plate 11, 13 first sheet structures 12, and 6 second sheet structures 13. The base plate 11 may be, for example, a rectangular sheet structure. Four side edges of the base plate 11 may be respectively defined as a first side edge 111A, a second side edge 111B, a third side edge 111C, and a fourth side edge 111D. The first side edge 111A is not adjacent to the second side edge 111B, and the first side edge 111A and the second side edge 111B are located opposite to each other. The third side edge 111C and the fourth side edge 111D are located opposite to each other, and the first side edge 111A is arranged adjacent to the third side edge 111C and the fourth side edge 111D. An appearance and a size of the base plate 11 are not limited to those shown in the drawings.

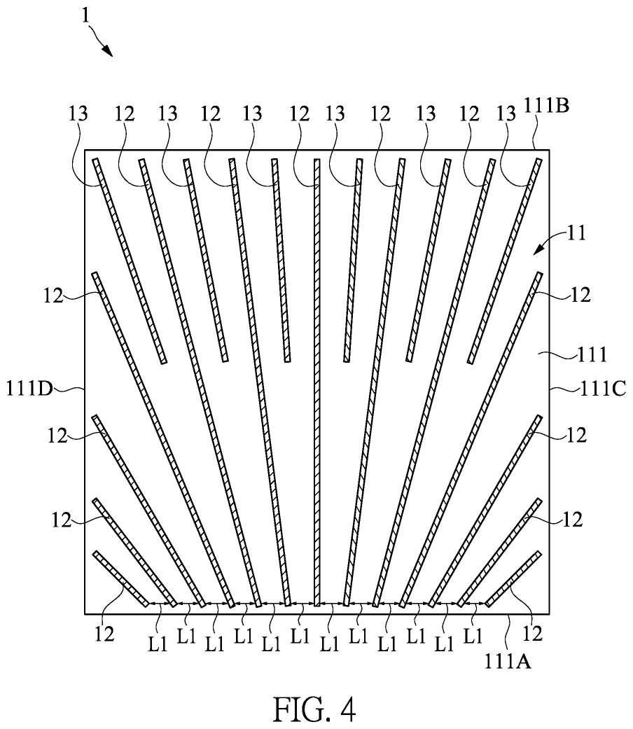

Each first sheet structure 12 is vertically arranged on a side surface 111 of the base plate 11. One end of the each first sheet structure 12 is arranged adjacent to the first side edge 111A. An other end of a part of the first sheet structures 12 is arranged adjacent to the second side edge 111B. An other end of a part of the first sheet structures 12 is adjacent to the third side edge 111C, and an other end of an other part of the first sheet structures 12 is arranged adjacent to the fourth side edge 111D. As shown in FIG. 4, in the top view of the heat dissipation member 1, a spacing between two adjacent first sheet structures 12 gradually increases from the first side edge 111A to the second side edge 111B. A minimum spacing between the two adjacent first sheet structures 12 is defined as a preset spacing L1. In a specific embodiment, the minimum spacing between any two adjacent first sheet structures 12 is the same. That is to say, all preset spacings L1 shown in FIG. 4 are the same.

Each second sheet structure 13 is arranged between two adjacent first sheet structures 12. A minimum spacing L3 between one end of the each second sheet structure 13 and an adjacent first sheet structure 12 is not greater than twice the preset spacing L1. Preferably, the minimum spacing L3 between one end of the each second sheet structure 13 and the adjacent first sheet structure 12 is approximately the same as the preset spacing L1, and a minimum spacing L2 between the two first sheet structures 12 adjacent to one end of the each second sheet structure 13 is approximately equal to twice the preset spacing L1. That is to say, one second sheet structure 13 is arranged at a position at which a spacing between the two adjacent first sheet structures 12 is greater than or equal to twice the preset spacing L1. An other end of the each second sheet structure 13 is arranged adjacent to the second side edge 111B of the base plate 11, which is not limited thereto. In different embodiments, an other end of a part of the second sheet structures 13 may alternatively be arranged adjacent to the third side edge 111C or the fourth side edge 111D. In addition, the spacing between the each second sheet structure 13 and any of the adjacent first sheet structures 12 gradually increases from the first side edge 111A to the second side edge 111B.

A number of the first sheet structures 12 and a number of the second sheet structures 13 included in the heat dissipation member 1 are not limited to those shown in the figures. The number of the second sheet structures 13 is mainly related to the size of the base plate 11 and the number of the first sheet structures 12. In practical application, the base plate 11, the each first sheet structure 12, and the each second sheet structure 13 may be integrally formed by using the die casting technology.

Based on the above, as shown in FIG. 3 to FIG. 5, the heat dissipation member 1 of the disclosure is designed through the plurality of first sheet structures 12 and the plurality of second sheet structures 13. In this way, when the heat dissipation member 1 is arranged on a to-be-dissipated device in a form of wall hanging (that is to say, the side surface 111 of the base plate 11 is arranged substantially perpendicular to the ground, and the first side edge 111A of the base plate 11 is arranged adjacent to the ground), part of air may enter the heat dissipation member 1 from the first side edge 111A of the base plate 11 along a first path P1, and flow out of the heat dissipation member 1 from the third side edge 111C or the fourth side edge 111D. Therefore, heat energy can disperse from the heat dissipation member 1 relatively quickly. Another part of the air can first flow into the heat dissipation member 1 along a second path P2, and then flow out of the heat dissipation member 1 along a third path P3. In this way, the problem that the heat energy is accumulated at a middle position of the heat dissipation member 1 can be effectively alleviated, thereby effectively improving the overall heat dissipation effect of the heat dissipation member 1.

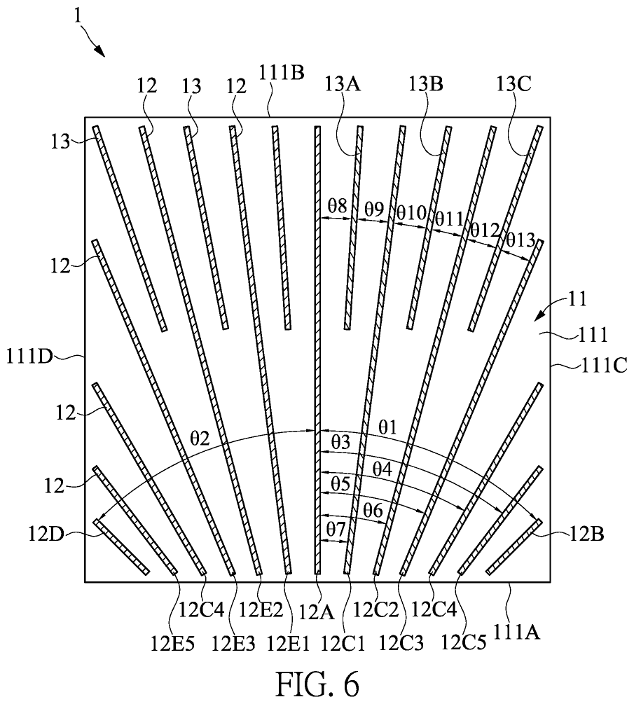

Referring to FIG. 3 to FIG. 6 together, FIG. 6 shows a top view of a heat dissipation member. Each first sheet structure and each second sheet structure shown in FIG. 6 are represented as an orthographic projection of each first sheet structure 12 on the side surface 111 of the base plate 11 and an orthographic projection of each second sheet structure 13 on the side surface 111 of the base plate 11. In a preferred embodiment, an included angle 01 between an orthographic projection of the first sheet structure 12B closest to the third side edge 111C on the side surface 111 of the base plate 11 and an orthographic projection of the first sheet structure 12A at a central position of the first side edge 111A on the side surface 111 is 45 degrees. An included angle 02 between an orthographic projection of the first sheet structure 12D closest to the fourth side edge 111D on the side surface 111 and an orthographic projection of the first sheet structure 12A at a central position of the first side edge 111A on the side surface 111 is 45 degrees. An included angle between an orthographic projection of each of the first sheet structures 12C1-12C5 away from the central position of the first side edge 111A on the side surface 111 and an orthographic projection of the first sheet structure 12A at the central position of the first side edge 111A on the side surface 111 of the base plate 11 is between 5 degrees and 45 degrees. An included angle between an orthographic projection of each second sheet structure 12 on the side surface 111 and an orthographic projection of an adjacent first sheet structure 12 on the side surface is between 5 degrees and 10 degrees. Two included angles between the orthographic projection of the second sheet structure 12 on the side surface 111 and orthographic projections of two first sheet structures 12 on two adjacent sides on the side surface 111 are equal.

Carrying on with the above, for example, included angles θ3-θ7 between orthographic projections of the first sheet structures 12C1-12C5 shown in FIG. 6 on the side surface 111 and orthographic projections of the first sheet structure 12A on the side surface 111 are between 5 degrees and 45 degrees. Included angles θ8-θ13 between orthographic projections of the second sheet structures 13A-13C on the side surface 111 and two first sheet structures 12A and 12C1-12C3 on two adjacent sides on the side surface are between 5 degrees and 10 degrees. The included angles θ8 and θ9 are equal, the included angles θ10 and θ11 are equal, and the included angles θ12 and θ13 are equal. Through the design of the foregoing included angles, the heat dissipation effect of the heat dissipation member 1 when hung on a to-be-dissipated member may further be improved.

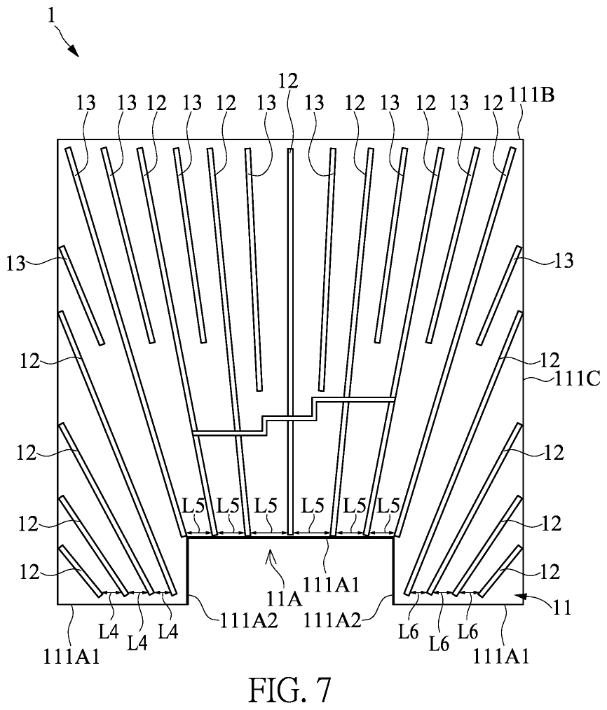

Referring to FIG. 7, FIG. 7 shows a top view of a second embodiment of a heat dissipation member according to the disclosure. A difference between this embodiment and the above embodiments lies in that an avoidance notch 11A is further formed on the first side edge 111A of the base plate 11, and the first side edge 111A of the base plate 11 is partitioned into two transverse sections 111A1 and two longitudinal sections 111A2. The heat dissipation member 1 is configured to be vertically hung on a to-be-dissipated electronic device, and the avoidance notch 11A is configured to accommodate a protruding structure of the electronic device. In other words, an appearance and a size of the avoidance notch 11A are designed according to an appearance and a size of the protruding structure of the electronic device, and the appearance and the size of the avoidance notch 11A shown in the figure are only examples.

One ends of four first sheet structures 12 are arranged adjacent to one transverse section 111A1 of the first side edge 111A. One ends of seven first sheet structures 12 are arranged adjacent to one transverse section 111A1 of the first side edge 111A, and other four first sheet structures 12 are arranged adjacent to another transverse section 111A1 of the first side edge 111A. In the drawings of this embodiment, one end of the each first sheet structure 12 is arranged only adjacent to one transverse section 111A1, and one end of the each first sheet structure 12 is not arranged adjacent to any longitudinal section 111A2 by way of example, which is not limited thereto. In different embodiments, at least one first sheet structure 12 may alternatively be arranged adjacent to one longitudinal section 111A2.

In addition, a preset spacing L4 (L5, L6) among the plurality of first sheet structures 12 adjacent to a same transverse section 111A1 may be exactly the same, and the preset spacings L4, L5, and L6 among the plurality of first sheet structures adjacent to different transverse sections 111A1 may not be exactly the same.

Based on the above, when the heat dissipation member of the disclosure is arranged on the to-be-dissipated electronic device in the form of wall hanging, the heat energy is relatively not easily accumulated at the middle position of the heat dissipation member, and the heat dissipation member has a better overall heat dissipation effect.

The above are only preferred feasible embodiments of the present invention, and are not intended to limit the patent scope of the present invention. Any equivalent structural changes made based on the contents of the specification and the drawings of the present invention shall all fall within the protection scope of the present invention.

What is claimed is:

1. A heat dissipation member, comprising:
a base plate, comprising a first side edge and a second side edge that are not adjacent;
a plurality of first sheet structures, wherein each first sheet structure is vertically arranged on the base plate, one end of the each first sheet structure is arranged adjacent to the first side edge, a spacing between two adjacent first sheet structures gradually increases from the first side edge to the second side edge, an other end of a part of the first sheet structures is arranged adjacent to a third side edge of the base plate, and the third side edge is adjacent to the first side edge; and
a plurality of second sheet structures, wherein each second sheet structure is arranged between two adjacent first sheet structures.

2. The heat dissipation member according to claim 1, wherein a minimum spacing between the two adjacent first sheet structures is defined as a preset spacing, and a spacing between one end of the each second sheet structure and an adjacent first sheet structure is not greater than twice the preset spacing.

3. The heat dissipation member according to claim 2, wherein a minimum spacing between any two adjacent first sheet structures is the same.

4. The heat dissipation member according to claim 1, wherein the first sheet structure is a side surface vertically arranged on the base plate, and an included angle between an orthographic projection of the first sheet structure away from a central position of the first side edge on the side surface and an orthographic projection of the first sheet structure at the central position of the first side edge on the side surface of the base plate is between 5 degrees and 45 degrees.

5. The heat dissipation member according to claim 4, wherein the base plate is a rectangular flat plate, the base plate comprises a first side edge, a second side edge, a third side edge, and a fourth side edge, the first side edge and the second side edge are opposite to each other on the base plate, the third side edge and the fourth side edge are opposite to each other on the base plate, an included angle between an orthographic projection of the first sheet structure closest to the third side edge on the side surface and an orthographic projection of the first sheet structure at the central position of the first side edge on the side surface is 45 degrees, and an included angle between an orthographic projection of the first sheet structure closest to the fourth side edge on the side surface and an orthographic projection of the first sheet structure at the central position of the first side edge on the side surface is 45 degrees.

6. The heat dissipation member according to claim 4, wherein an included angle between an orthographic projection of the each second sheet structure on a plane of the base plate and an orthographic projection of an adjacent first sheet structure on the plane of the base plate is between 5 degrees and 10 degrees.

7. The heat dissipation member according to claim 6, wherein two included angles between the orthographic projection of the second sheet structure on the plane of the base plate and an orthographic projection of each of two first sheet structures on two adjacent sides on the plane of the base plate are equal.

8. The heat dissipation member according to claim 1, wherein a spacing between the each second sheet structure and any adjacent first sheet structure gradually increases from the first side edge to the second side edge.

9. The heat dissipation member according to claim 1, wherein an avoidance notch is formed on the first side edge of the base plate, the first side edge of the base plate is partitioned into a plurality of transverse sections and a plurality of longitudinal sections, and an end of at least part of the first sheet structures is arranged adjacent to one of the transverse sections.
